(19) United States
(12) Patent Application Publication
(10) Pub. No.: US 2021/0328148 A1
(43) Pub. Date: Oct. 21, 2021

(54) SEMICONDUCTOR MIXED MATERIAL AND MANUFACTURING METHOD THEREOF, THIN FILM TRANSISTOR AND ELECTRONIC DEVICE

(71) Applicants: CHONGQING BOE OPTOELECTRONICS TECHNOLOGY CO., LTD., Chongqing (CN); BOE TECHNOLOGY GROUP CO., LTD., Beijing (CN)

(72) Inventors: Xiaonan DONG, Beijing (CN); Chao ZHANG, Beijing (CN); Kunkun GAO, Beijing (CN); Zhonghao HUANG, Beijing (CN); Yongliang ZHAO, Beijing (CN)

(21) Appl. No.: 16/328,423

(22) PCT Filed: Apr. 23, 2018
(86) PCT No.: PCT/CN2018/084097

§ 371 Date: Feb. 26, 2019

(30) Foreign Application Priority Data
Aug. 25, 2017 (CN) 201710743461.1

(51) Int. Cl. H01L 51/00; C08K 3/36; C08K 3/22; C08K 9/10; C08K 3/08; C08J 3/20

(52) U.S. Cl. CPC H01L 51/0036; C08K 3/36; C08K 3/22; C08K 9/10; H01L 51/0566; C08J 3/203; H01L 2251/303; H01L 2251/301; C08K 3/08

(57) ABSTRACT

A semiconductor mixed material and manufacturing method thereof, a thin film transistor and an electronic device are provided. The semiconductor mixed material includes an inorganic semiconductor nanoparticle and an organic semiconductor material, and the inorganic semiconductor nanoparticle is dispersed in the organic semiconductor material. The embodiments of the present disclosure ensure both a high electron mobility and a high charge transfer rate by mixing the inorganic semiconductor nanoparticle with the organic semiconductor material.

The present application claims the priority of the Chinese Patent Application No. 201710743461.1 filed on Aug. 25, 2017, which is incorporated herein by reference as a part of the present application.

### TECHNICAL FIELD

Embodiments of the present disclosure relate to a semiconductor mixed material, a manufacturing method of the semiconductor mixed material, a thin film transistor and an electronic device.

### BACKGROUND

A variety of display devices such as, a liquid crystal display (LCD), a plasma display panel (PDP), a field emission display (FED), and an organic light emitting display (OLED) have been widely used. Passive matrix addressing schemes or active matrix addressing schemes of thin film transistors can be used for addressing.

In an active matrix addressing scheme, electron mobility, leakage current, and durability and electrical reliability required to ensure a long service life are very important for a thin film transistor. Currently, a material of the active layer of the thin film transistor comprises one of amorphous silicon, polysilicon, oxide semiconductor and organic semiconductor. The active layer manufactured by the above materials has advantages or disadvantages in charge mobility, charge transfer rate, capability of capturing electrons, leakage current, durability and electrical reliability required to ensure a long service life. Thus, improving charge mobility, charge transfer rate, capability of capturing electrons, leakage current and on/off ratio of the thin film transistor simultaneously is a technical problem to be solved.

### SUMMARY

At least one embodiment of the present disclosure provides a semiconductor mixed material, and the semiconductor mixed material comprises: an inorganic semiconductor nanoparticle and an organic semiconductor material, and the inorganic semiconductor nanoparticle is dispersed in the organic semiconductor material.

For example, in the semiconductor mixed material provided by at least one embodiment of the present disclosure, the inorganic semiconductor nanoparticle comprises at least one of an element semiconductor nanoparticle and a compound semiconductor nanoparticle.

For example, in the semiconductor mixed material provided by at least one embodiment of the present disclosure, the element semiconductor nanoparticle comprises at least one of silicon nanoparticle and germanium nanoparticle; and the compound semiconductor nanoparticle comprises at least one of titanium dioxide nanoparticle, zinc sulfide nanoparticle, gallium arsenide nanoparticle, tin oxide nanoparticle, indium oxide nanoparticle, indium antimonide nanoparticle, indium phosphide nanoparticle, cadmium sulfide nanoparticle, bismuth telluride nanoparticle, cuprous oxide nanoparticle, gallium aluminum arsenide nanoparticle, indium gallium arsenide phosphide nanoparticle, gallium arsenide phosphide nanoparticle and copper indium selenide nanoparticle.

For example, in the semiconductor mixed material provided by at least one embodiment of the present disclosure, in a case that the inorganic semiconductor nanoparticle is titanium dioxide nanoparticle, at least a portion of a surface of the titanium dioxide nanoparticle is covered with silver.

For example, in the semiconductor mixed material provided by at least one embodiment of the present disclosure, the organic semiconductor material comprises at least one of phthalocyanine, triphenyl amine, polyacetylene and polyaromatic ring.

For example, in the semiconductor mixed material provided by at least one embodiment of the present disclosure, the polyaromatic ring comprises at least one of polybenzene, polythiophene, polyaniline and polypyrrole.

For example, in the semiconductor mixed material provided by at least one embodiment of the present disclosure, the polythiophene comprises poly (3-hexylthiophene).

For example, the semiconductor mixed material provided by at least one embodiment of the present disclosure further comprises: a coupling agent, wherein the coupling agent comprises at least one of poly (perfluorosulfonic acid), silane coupling agent, ethylene glycol, polyvinyl alcohol and glycerol.

For example, the semiconductor mixed material provided by at least one embodiment of the present disclosure further comprises: a room temperature ionic liquid, wherein the room temperature ionic liquid comprises at least one of 1,3-dialkyl imidazolium tetrafluoroborate, 1-alkyl-3-methyl imidazolium hexafluorophosphate, 1-butyl-3-methyl imidazolium hexafluorophosphate and 1-allyl-3-methyl imidazolium carboxylate, 1-methyl-3-methyl imidazolium tetrafluoroborate, 1-ethyl-3-methyl imidazolium tetrafluoroborate, N,N-dialkyl imidazolium hexafluorophosphate, N,N-dialkyl imidazolium bromide hexafluorophosphate.

At least one embodiment of the present disclosure further provides a thin film transistor, and the thin film transistor includes an active layer which comprises any one of the semiconductor mixed materials described above.

For example, the thin film transistor provided by at least one embodiment of the present disclosure further comprises: a source electrode, a drain electrode and an organic semiconductor layer, wherein the organic semiconductor layer is arranged at a side of the active layer away from the source electrode and the drain electrode.

For example, in the thin film transistor provided by at least one embodiment of the present disclosure, a material of the organic semiconductor layer is poly (3-hexylthiophene).

At least one embodiment of the present disclosure further provides an electronic device, and the electronic device comprises any one of the thin film transistors described above.

At least one embodiment of the present disclosure further provides a manufacturing method of a semiconductor mixed material, and the method comprises: dispersing an inorganic semiconductor nanoparticle in an organic semiconductor material.

For example, the manufacturing method provided by at least one embodiment of the present disclosure further comprises: mixing the inorganic semiconductor nanoparticle with a coupling agent and a room temperature ionic liquid, and then being stirred and separated by centrifugation to form a composite structure which has the inorganic semiconductor nanoparticle coated with the coupling agent and the room temperature ionic liquid.

At least one embodiment of the present disclosure further provides a manufacturing method of a thin film transistor, and the method comprises: providing a base substrate; and forming a gate electrode, an active layer, an organic semiconductor layer, a source electrode and a drain electrode on the base substrate, wherein the forming the active layer includes forming any one of the semiconductor mixed materials on the base substrate, and the forming the organic semiconductor layer includes forming an organic semiconductor material on a side of the active layer away from the source electrode and the drain electrode.

### BRIEF DESCRIPTION OF THE DRAWINGS

In order to clearly illustrate the technical solution of the embodiments of the present disclosure, the drawings of the embodiments will be briefly described. It is apparent that the described drawings are only related to some embodiments of the present disclosure and thus are not limitative of the present disclosure.

FIG. 1 is a schematic diagram of a sectional structure of a thin film transistor provided by one embodiment of the present disclosure;

FIG. 2 is a block diagram of an electronic device provided by one embodiment of the present disclosure;

FIG. 3 is a scanning electron microscopy image of titanium dioxide nanocrystals provided by one embodiment of the present disclosure;

FIG. 4 is a transmission electron microscopy image of Ag—TiO₂ nanocrystals provided by one embodiment of the present disclosure;

FIG. 5 is a X-ray photoelectron spectroscopy of Ag—TiO₂ nanocrystals provided by one embodiment of the present disclosure;

FIG. 6 is a X-ray diffraction pattern of Ag—TiO₂ nanocrystals provided by one embodiment of the present disclosure;

FIG. 7 is a UV-Vis absorption spectrum of Ag—TiO₂ nanocrystals provided by one embodiment of the present disclosure; and

FIG. 8 is a flow chart of a manufacturing method of a thin film transistor provided by one embodiment of the present disclosure.

### REFERENCE NUMERALS

10—thin film transistor; 11—base substrate; 12—gate electrode; 13—gate insulation layer; 14—organic semiconductor layer; 15—active layer; 16—source electrode; 17—drain electrode; 20—electronic device.

### DETAILED DESCRIPTION

In order to make objects, technical details and advantages of embodiments of the disclosure clear, the technical solutions of the embodiments will be described in a clearly and fully understandable way in connection with the related drawings. It is apparent that the described embodiments are just a part but not all of the embodiments of the disclosure. Based on the described embodiments herein, those skilled in the art can obtain, without any inventive work, other embodiment(s) which should be within the scope of the disclosure.

Unless otherwise defined, all the technical and scientific terms used herein have the same meanings as commonly understood by one of ordinary skill in the art to which the present invention belongs. The terms “first,” “second,” etc., which are used in the description and claims of the present application, are not intended to indicate any sequence, amount or importance, but to distinguish various components. The terms “comprises,” “comprising,” “includes,” “including,” etc., are intended to specify that the elements or the objects stated before these terms encompass the elements or the objects listed after these terms as well as equivalents thereof, but do not exclude other elements or objects. The phrases “connect”, “connected”, etc., are not intended to define a physical connection or mechanical connection, but may include an electrical connection which is direct or indirect. The terms “on,” “under,” “right,” “left” and the like are only used to indicate relative position relationship, and when the position of an object is described as being changed, the relative position relationship may be changed accordingly.

The inventors of the present disclosure find that, in the conventional materials for manufacturing a semiconductor layer, a main advantage of amorphous silicon is that it can simplify the deposition process and reduce the manufacturing cost, but the amorphous silicon has a lower electron mobility than that of other inorganic semiconductor materials. In contrast, polysilicon has a high electron mobility of about 100 cm²/Vs, but it has a lower on/off ratio compared with oxide semiconductors, and the cost of using polysilicon in a large scale electronic device is higher. Oxide semiconductors have an on/off ratio of about 108 and a low leakage current, but have a lower electron mobility than polysilicon. Organic semiconductors have a much lower charge mobility than that of inorganic semiconductors, but organic semiconductors have a strong ability of capturing electrons. In this way the characteristics of a semiconductor layer can be improved by combining the advantage of the high charge mobility of an inorganic semiconductor material with the advantage of the strong electron-capturing ability of an organic semiconductor material.

At least one embodiment of the present disclosure provides a semiconductor mixed material which comprises an inorganic semiconductor nanoparticle and an organic semiconductor material, and the inorganic semiconductor nanoparticle is dispersed in the organic semiconductor material. The present disclosure improves electrical properties of the entire semiconductor layer by combining the advantage of the high charge mobility of the inorganic semiconductor material with the advantages of the strong electron-capturing ability and the fast charge transfer rate of the organic semiconductor material.

At least one embodiment of the present disclosure provides the semiconductor mixed material which comprises inorganic semiconductor nanoparticles and an organic semiconductor material, and the inorganic semiconductor nanoparticles are dispersed in the organic semiconductor material.

For example, the inorganic semiconductor nanoparticles are dispersed in the organic semiconductor material uniformly to make the charge mobilities in various places of the semiconductor layer subsequently formed equal.

For example, the inorganic semiconductor nanoparticles comprise at least one of element semiconductor nanoparticles and compound semiconductor nanoparticles.

It should be noted that, the “nanoparticles” in the element semiconductor nanoparticles and the compound semiconductor nanoparticles are nanometer particles, and the shape of the nanometer particles is not limited to a regular sphere. For example, the nanometer particles may be particles having a certain aspect ratio such as a shape of ellipsoidal, cylindrical and so on. The particle size of the nanometer particles (may be an equivalent particle size) ranges from about 1 nm to about 500 nm, specifically, from about 10 nm to about 300 nm; more specifically from about 50 nm to about 150 nm.

For example, the particle size of the nanometer particles is about 10 nm, 30 nm, 50 nm, 100 nm, 200 nm, 250 nm, 350 nm, 400 nm or 500 nm.

For example, the element semiconductor nanoparticle comprises at least one of silicon nanoparticle and germanium nanoparticle. For example, the element semiconductor nanoparticle comprises monocrystalline silicon, polycrystalline silicon, monocrystalline germanium or polycrystalline germanium, etc.

For example, the compound semiconductor nanoparticle comprises at least one of titanium dioxide nanoparticle, zinc sulfide nanoparticle, gallium arsenide nanoparticle, tin oxide nanoparticle, indium oxide nanoparticle, indium antimonide nanoparticle, indium phosphide nanoparticle, cadmium sulfide nanoparticle, bismuth telluride nanoparticle, cuprous oxide nanoparticle, gallium aluminum arsenide nanoparticle, indium gallium arsenide phosphide nanoparticle, gallium arsenide phosphide nanoparticle and copper indium selenide nanoparticle.

For example, metal oxide semiconductor materials are widely used in active matrix due to their unique properties. In all kinds of metal oxides, the titanium dioxide nanoparticle has been widely used due to its simple synthesis process, low cost, low toxicity, good stability, long service life and high biological affinity. As an environmental-friendly semiconductor material, the titanium dioxide nanoparticle is often used as a material of a channel region of a transistor. Based on a quantum size effect and a surface effect of a nanomaterial, the structure and properties of the titanium dioxide nanocrystalline material are different from those of a bulk material. However, the titanium dioxide nanocrystalline material has a larger forbidden band width and belongs to an n-type semiconductor material with a wide band gap. The forbidden band width of the titanium dioxide nanocrystalline material is 3.2 eV and can be reduced by modifying the titanium dioxide nanocrystalline material with a noble metal such as silver and gold so as to improve the charge mobility of the titanium dioxide nanocrystalline material.

However, when a film is formed, the nanocrystalline material modified with the noble metal has some problems such as an uneven thickness of the film, a weak adhesion of the film-forming particles, and a tendency to crack. In addition, when the silver-modified titanium dioxide nanocrystalline material is used, a problem that its direct contact with a source electrode and a drain electrode results in electrical conduction needs to be solved. Therefore the silver-modified titanium dioxide nanocrystalline material needs to cooperate with another kind of semiconductor material in order to solve the problem of electrical conduction.

For example, organic semiconductor is an organic material having a semiconductor property. Compared with an inorganic semiconductor material, the organic semiconductor material has a unique property. For example, the organic semiconductor material has more film-forming techniques, such as vacuum evaporation, solution spin-coating, Langmtrir-Blodgett (LB), and molecular self-assembly. The organic semiconductor material can afford a simple fabrication process, various manufacturing methods, and a low production cost, and a large scale manufacturing technology of the organic semiconductor material can be used to fabricate a large-scale device.

For example, in the semiconductor mixed material provided by at least one embodiment of the present disclosure, the organic semiconductor material comprises at least one of phthalocyanine, triphenyl amine, polyacetylene and polyaromatic ring.

For example, in the semiconductor mixed material provided by at least one embodiment of the present disclosure, the polyaromatic ring comprises at least one of polybenzene, polythiophene, polyaniline and polypyrrole.

For example, in the semiconductor mixed material provided by at least one embodiment of the present disclosure, the polythiophene comprises poly (3-hexylthiophene).

For example, the organic semiconductor material may further comprise polymeric organic semiconductors, such as F8T2 (poly [(9,9-dioctylfluorenyl-2,7-diyl)-co-(bithiophene)]) and P3DDT (poly (3-dodecyl thiophene-2,5-diyl)), P3HT (poly (3-hexylthiophene-2,5-diyl)), MDMOPPV (Poly [2-methoxy-5-(3′,7′-dimethyl octyloxy)-1,4-phenylene vinylene), MEH-PPV (poly [2-methoxy-5-(2-ethylhexyloxy)-1,4-phenylene vinylene]) and P3OT (Poly (3-octylthiophene-2,5-diyl)).

For example, the organic semiconductor material may further comprise small molecular organic semiconductor material such as TIPS-pentacene (6,13-bis (triisopropylsilyl ethynyl) pentacene), TESPentacene (6,13-bis((triethylsilyl)ethynyl) pentacene), DH-FTTF (5,5′-bis (7-hexyl-9H-fluoren-2-yl)-2,2′-bithiophene), DH2T (5,5′-dihexyl-2,2′-bithiophene) and TES-ADT (5,11-bis((triethylsilyl) ethynyl) anthradithiophene).

For example, an organic semiconductor material such as poly (3-hexylthiophene) is mixed with the titanium dioxide nanocrystalline material at least partially coated with silver. The organic semiconductor material is directly contacted with the source electrode and the drain electrode, which can solve the problem that direct contact between the silver-modified titanium dioxide nanocrystalline material with the source electrode and the drain electrode results in electrical conduction.

For example, the electron mobility of the organic semiconductor material is very low because there are a large number of electron traps in the organic semiconductor material. Therefore, both a high electron mobility and a high charge transfer rate can be ensured by combining the inorganic semiconductor material with the organic semiconductor material.

For example, if a film-forming property of a mixed material of the organic semiconductor material and the inorganic semiconductor material is poor, a coupling agent may be added to improve the uniformity of the formed film.

For example, the semiconductor mixed material provided by at least one embodiment of the present disclosure may further comprise a coupling agent, and the coupling agent comprises at least one of poly (perfluorosulfonic acid), silane coupling agent, ethylene glycol, polyvinyl alcohol and glycerol.

For example, because the mobility of the charge at an interface between the inorganic semiconductor material and the organic semiconductor material is very low, the charge mobility at the interface between the inorganic semiconductor material and the organic semiconductor material can be improved by adding a room temperature ionic liquid.

For example, the semiconductor mixed material provided by at least one embodiment of the present disclosure may further comprise a room temperature ionic liquid, and the room temperature ionic liquid comprises at least one of 1,3-dialkyl imidazolium tetrafluoroborate, 1-alkyl-3-methyl imidazolium hexalluorophosphate, 1-butyl-3-methyl imidazolium hexafluorophosphate and 1-allyl-3-methyl imidazolium carboxylate, 1-methyl-3-methyl imidazolium tetrafluoroborate, 1-ethyl-3-methyl imidazolium tetrafluoroborate, N,N-dialkyl imidazolium hexafluorophosphate, N,N-dialkyl imidazolium bromide hexafluorophosphate.

For example, 1,3-dialkyl imidazolium tetrafluoroborate is a common room temperature ionic liquid, and can be synthesized as follows: (1) using N-alkyl imidazole and haloalkane as starting materials and using acetone, toluene, acetonitrile or trichloroethane as a solvent to manufacture 1,3-dialkyl imidazole ammonium halide; (2) reacting the prepared ammonium halide with tetrafluoroborate in an organic solvent such as acetonitrile, acetone, and trichloroethane or water to obtain the room temperature ionic liquid.

The semiconductor mixed material provided by at least one embodiment of the present disclosure combines the advantages of high charge mobility and high stability of the inorganic semiconductor material with the advantages of high charge transfer rate, being easy to be modified and processed, and flexibility of the organic material. One or more functional interfaces can be formed between the organic semiconductor material and the inorganic semiconductor material, which not only preserves an intrinsic property of each original component, but also produces a new property by a strong interfacial interaction. That is, a synergism of “1+1>2” is realized, and it shows superior performances in electrical properties that the single organic semiconductor material or the single inorganic semiconductor material does not possess.

At least one embodiment of the present disclosure further comprises a thin film transistor, and the thin film transistor comprises: an active layer comprising any one of the semiconductor mixed materials mentioned above.

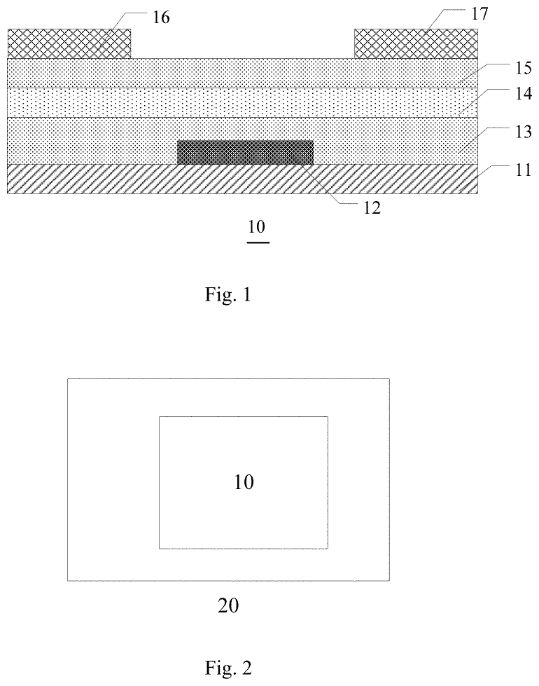

For example, FIG. 1 is a schematic diagram of a sectional structure of a thin film transistor provided by at least one embodiment of the present disclosure. As illustrated in FIG. 1, the film transistor 10 is a bottom-gate type thin film transistor. The thin film transistor comprises a base substrate 11, a gate electrode 12 and a gate insulation layer 13 disposed on the base substrate 11, an organic semiconductor layer 14 disposed on the gate insulation layer 13, an active layer 15 arranged on the organic semiconductor layer 14, and a source electrode 16 and a drain electrode 17 arranged on the active layer 15. That is, the organic semiconductor layer 14 is arranged on a side of the active layer 15 facing away from the source electrode 16 and the drain electrode 17.

For example, in a case that the thin film transistor is a top-gate type thin film transistor, the organic semiconductor layer is also arranged on the side of the active layer facing away from the source electrode and the drain electrode. The structure of the top-gate type thin film transistor can refer to a conventional top-gate type structure, which is omitted herein.

For example, in the thin film transistor provided by an embodiment of the present disclosure, the material of the organic semiconductor layer is poly(3-hexylthiophene). For example, the active layer formed by titanium dioxide nanocrystals at least partially coated with silver, poly (perfluorosulfonic acid), a room temperature ionic liquid and poly(3-hexylthiophene) is connected to the organic semiconductor layer made of poly(3-hexylthiophene) through π-π bonds to form stereo channels of organic semiconductor layer so as to further improve the charge mobility.

At least one embodiment of the present disclosure further provides an electronic device, and the electronic device comprises any one of the thin film transistors mentioned above. For example, FIG. 2 is a block diagram of an electronic device provided by one embodiment of the present disclosure. As illustrated in FIG. 2, the electronic device 20 comprises the thin film transistor 10.

For example, other structures of the electronic device 20 can refer to a conventional design.

The electronic device may be a display device, and the display device for example is: a mobile phone, a tablet computer, a television, a display, a notebook computer, a digital picture frame, a navigation system and any other product or component having a display function. Other essential components of a display device understood by those skilled in the art are included, which are omitted herein and should not be a limitation of the present disclosure. Embodiments of the electronic device are omitted herein due to reference to the embodiments of the thin film transistor described above.

At least one embodiment of the present disclosure further provides a manufacturing method of a semiconductor mixed material, and the method comprises: dispersing an inorganic semiconductor nanoparticle in an organic semiconductor material.

For example, the manufacturing method provided by an embodiment of the present disclosure may further comprise: mixing the inorganic semiconductor nanoparticle with a coupling agent and a room temperature ionic liquid, and then being stirred and separated by centrifugation to form a composite structure which has the inorganic semiconductor nanoparticle coated with the coupling agent and the room temperature ionic liquid.

In the following examples, the titanium dioxide nanocrystals modified by silver are coated with a coupling agent (for example, poly (perfluorosulfonic acid)) and a room temperature ionic liquid (for example, 1-alkyl-3-methyl imidazolium hexafluorophosphate), and the organic semiconductor material is poly(3-hexylthiophene).

For example, the manufacturing method of titanium dioxide nanocrystals modified by silver is described below.

### Example 1

Adding 10 mL silver nitrate solution with a mass concentration of 1 g/L into 500 mL glacial acetic acid solution with a mass percentage of 98.5%, then stirring continuously for 20 minutes to form a well-dispersed light yellow system. Dripping 8 mL titanium isopropoxide into the glacial acetic acid mixture system slowly and stirring continuously for 40 minutes to obtain a mixed solution. Transferring the above mixed solution to at least one (for example, 5) reactor with a stainless steel shell and a polytetrafluoroethylene lining averagely and keeping at 180° C. for 10 hours to obtain a gray-white product, separating the gray-white product by centrifugation with a rotating speed of 7000 r/min, and then washing the gray-white product with ethanol and deionized water each for three times, then vacuum drying to obtain the silver-modified titanium dioxide nanocrystals.

### Example 2

Adding 5 mL silver nitrate solution with a mass concentration of 35 g/L into 300 mL glacial acetic acid solution with a mass percentage of 98.5%, then stirring continuously for 20 minutes to form a well-dispersed light yellow system. Dripping 5 mL titanium isopropoxide into the glacial acetic acid mixture system slowly and stirring continuously for 20 minutes to obtain a mixed solution. Transferring the above mixed solution to at least one (for example, 5) reactor with a stainless steel shell and a polytetrafluoroethylene lining averagely and keeping at 160° C. for 20 hours to obtain a gray-white product, separating the gray-white product by centrifugation with a rotating speed of 6000 r/min, and then washing the gray-white product with ethanol and deionized water each for three times, then vacuum drying to obtain the silver-modified titanium dioxide nanocrystals.

### Example 3

Adding 1 mL silver nitrate solution with a mass concentration of 50 g/L into 200 mL glacial acetic acid solution with a mass percentage of 98.5%, then stirring continuously for 30 minutes to form a well-dispersed light yellow system. Dripping 1 mL titanium isopropoxide into the glacial acetic acid mixture system slowly and stirring continuously for 35 minutes to obtain a mixed solution. Transferring the above mixed solution to at least one (for example, 5) reactor with a stainless steel shell and a polytetrafluoroethylene lining averagely and keeping at 200° C. for 15 hours to obtain a gray-white product, separating the gray-white product by centrifugation with a rotating speed of 8000 r/min, and then washing the gray-white product with ethanol and deionized water each for three times, then vacuum drying to obtain the silver-modified titanium dioxide nanocrystals.

### Example 4

Adding 8 mL silver nitrate solution with a mass concentration of 10 g/L into 250 mL glacial acetic acid solution with a mass percentage of 98.5%, then stirring continuously for 35 minutes to form a well-dispersed light yellow system. Dripping 10 mL titanium isopropoxide into the glacial acetic acid mixture system slowly and stirring continuously for 30 minutes to obtain a mixed solution. Transferring the above mixed solution to at least one (for example, 5) reactor with a stainless steel shell and a polytetrafluoroethylene lining averagely and keeping at 120° C. for 18 hours to obtain a gray-white product, separating the gray-white product by centrifugation with a rotating speed of 5000 r/min, and then washing the gray-white product with ethanol and deionized water each for three times, then vacuum drying to obtain the silver-modified titanium dioxide nanocrystals.

It should be noted that, in Examples 1-4 described above, the mass concentration of silver nitrate solution is from 1 g/L to 50 g/L; the volume of the glacial acetic acid solution is from 200 mL to 500 mL; the stirring time is from 20 min to 40 min; the rotating speed of centrifugation is from 5000 r/m in to 8000 r/min; the reaction temperature in the reactor is from 120° C. to 200° C.; and the keeping time is from 10 h to 20 h. According to requirements, the above parameters can be selected within the above ranges, not limited to the specific values described in the above examples.

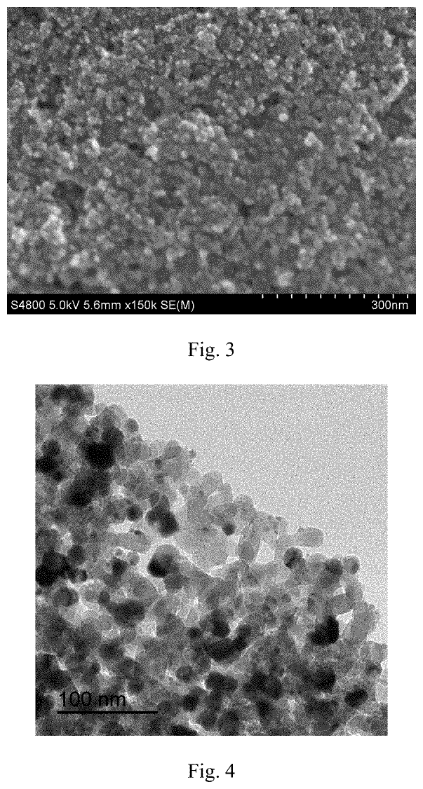

For example, FIG. 3 is a scanning electron microscopy image of titanium dioxide nanocrystals provided by one embodiment of the present disclosure. It can be seen from FIG. 3, the size of the titanium dioxide nanocrystalline is from 10 to 100 nm.

For example, FIG. 4 is a transmission electron microscopy image of Ag—TiO₂ nanocrystals provided by one embodiment of the present disclosure. FIG. 4 illustrates that at least a portion of a surface of TiO₂ nanocrystals is covered with Ag.

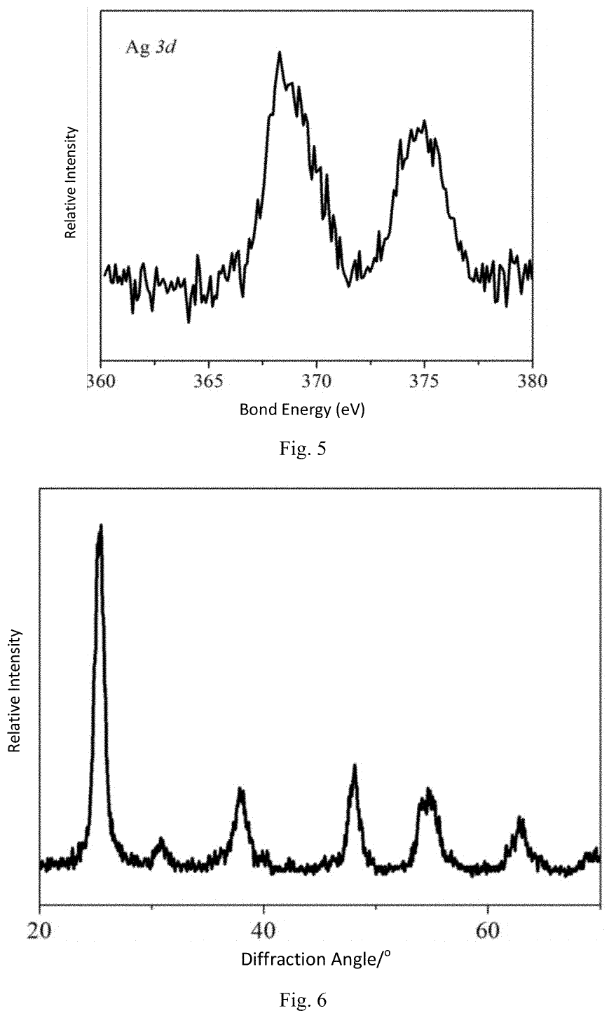

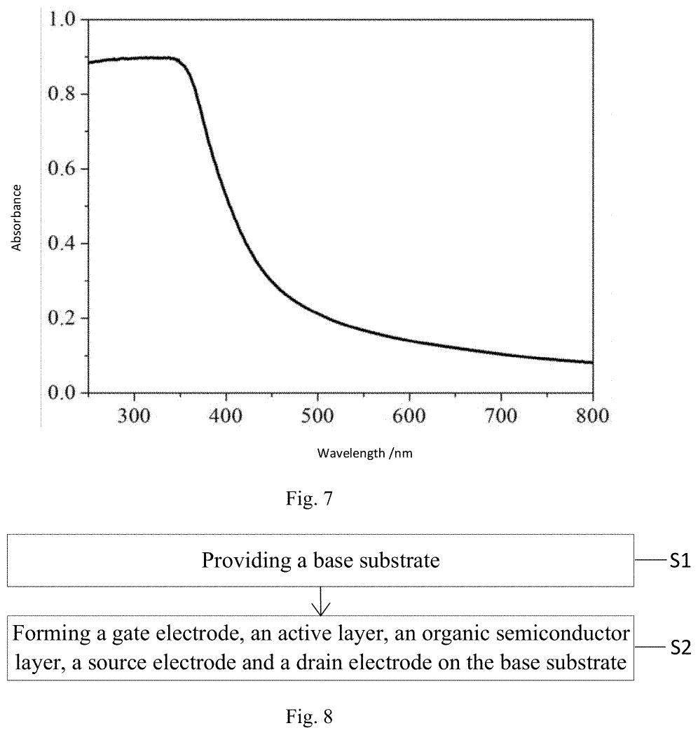

For example, FIG. 5 is an X-ray photoelectron spectroscopy of Ag—TiO₂ nanocrystals provided by one embodiment of the present disclosure; FIG. 6 is an X-ray diffraction pattern of Ag—TiO₂ nanocrystals provided by one embodiment of the present disclosure; FIG. 7 is a UV-Vis absorption spectrum of Ag—TiO₂ nanocrystals provided by one embodiment of the present disclosure. From FIG. 5 to FIG. 7, it is found that the formed metal oxide is TiO₂, and at least a portion of the surface of the TiO₂ particle is covered with Ag.

For example, the manufacturing method of the semiconductor mixed material is illustrated below.

### Example A

The silver-modified titanium dioxide nanocrystals, poly (perfluorosulfonic acid), and the room temperature ionic liquid are mixed under stirring to form an intimate mixture. The mixture is treated with ultrasound for 10 minutes (min) and then is separated by a centrifuge at a rotating speed of 6000 r/min. The process is repeated for three times. In the centrifugal separation, a centrifugal tube with a volume of 10 mL is used to load the mixture. The mass of the silver-modified titanium dioxide is 0.5 g, and the volume ratio of poly (perfluorosulfonic acid) to the room temperature ionic liquids is 1:5. Then the silver-modified titanium dioxide having poly (perfluorosulfonic acid) and the room temperature ionic liquid formed on the surface is mixed with poly(3-hexythiophene) uniformly to form a semiconductor mixed material of the silver-modified titanium dioxide nanocrystals, poly (perfluorosulfonic acid), the room temperature ionic liquid and poly (3-hexylthiophene).

### Example B

The silver-modified titanium dioxide nanocrystals, poly (perfluorosulfonic acid), and the room temperature ionic liquid are mixed under stirring to form an intimate mixture. The mixture is treated with ultrasound for 20 minutes and then is separated by a centrifuge at a rotating speed of 5000 r/min. The process is repeated for three times. In the centrifugal separation, a centrifugal tube with a volume of 10 mL is used to load the mixture. The mass of the silver-modified titanium dioxide is 0.5 g, and the volume ratio of poly (perfluorosulfonic acid) to the room temperature ionic liquids is 1:1. Then the silver-modified titanium dioxide having poly (perfluorosulfonic acid) and the room temperature ionic liquid formed on the surface is mixed with poly(3-hexythiophene) uniformly to form a semiconductor mixed material of the silver-modified titanium dioxide nanocrystals, poly (perfluorosulfonic acid), the room temperature ionic liquid and poly (3-hexylthiophene).

### Example C

The silver-modified titanium dioxide nanocrystals, poly (perfluorosulfonic acid), and the room temperature ionic liquid are mixed under stirring to form an intimate mixture. The mixture is treated with ultrasound for 15 minutes (min) and then is separated by a centrifuge at a rotating speed of 7000 r/min. The process is repeated for three times. In the centrifugal separation, a centrifugal tube with a volume of 10 mL is used to load the mixture. The mass of the silver-modified titanium dioxide is 0.5 g, and the volume ratio of poly (perfluorosulfonic acid) to the room temperature ionic liquids is 1:4. Then the silver-modified titanium dioxide having poly (perfluorosulfonic acid) and the room temperature ionic liquid formed on the surface is mixed with poly(3-hexythiophene) uniformly to form a semiconductor mixed material of the silver-modified titanium dioxide nanocrystals, poly (perfluorosulfonic acid), the room temperature ionic liquid and poly (3-hexylthiophene).

### Example D

The silver-modified titanium dioxide nanocrystals, poly (perfluorosulfonic acid), and the room temperature ionic liquid are mixed under stirring to form an intimate mixture. The mixture is treated with ultrasound for 15 minutes (min) and then is separated by a centrifuge at a rotating speed of 8000 r/min. The process is repeated for three times. In the centrifugal separation, a centrifugal tube with a volume of 10 mL is used to load the mixture. The mass of the silver-modified titanium dioxide is 0.5 g, and the volume ratio of poly (perfluorosulfonic acid) to the room temperature ionic liquids is 1:10. Then the silver-modified titanium dioxide having poly (perfluorosulfonic acid) and the room temperature ionic liquid formed on the surface is mixed with poly(3-hexythiophene) uniformly to form a semiconductor mixed material of the silver-modified titanium dioxide nanocrystals, poly (perfluorosulfonic acid), the room temperature ionic liquid and poly (3-hexylthiophene).

It should be noted that, in Examples A to D, the mass of the silver-modified titanium dioxide ranges from about 0.01 g to 1.0 g; the volume ratio of poly (perfluorosulfonic acid) to the room temperature ionic liquid is from about 1:1 to 1:10; and the rotating speed of centrifugation is from about 5000 r/min to 8000 r/min. According to requirements, these parameters can be selected from the above ranges, not limited to the specific values described in the examples.

At least one embodiment of the present disclosure further provides a manufacturing method of a thin film transistor. For example, FIG. 8 is a flow chart of a manufacturing method of a thin film transistor provided by one embodiment of the present disclosure, and the manufacturing method of the thin film transistor comprises the steps S1 to S2.

S1: providing a base substrate.

For example, the base substrate is a glass substrate or a resin substrate.

S2: forming a gate electrode, an active layer, an organic semiconductor layer, a source electrode and a drain electrode on the base substrate.

For example, forming the active layer comprises forming (for example, applying) any one of the semiconductor mixed materials on the base substrate.

For example, forming the organic semiconductor layer comprises forming (for example, applying) an organic semiconductor material on a side of the active layer away from the source electrode and the drain electrode.

For example, when the active layer or the organic semiconductor layer is to be formed in embodiments of the present disclosure, the semiconductor mixed material or the organic semiconductor material formed on the base substrate can be solidified directly without using a pattern technology, which reduces the process steps and saves the production cost.

The semiconductor mixed material, the manufacturing method of the semiconductor mixed material, the thin film transistor and the electronic device provided by at least one embodiment of the present disclosure have at least one of the following beneficial effects:

(1) In the semiconductor mixed material provided by at least one embodiment of the present disclosure, combination of the inorganic semiconductor nanoparticles and the organic semiconductor material ensures both a high electron mobility and a high charge transfer rate.

(2) The semiconductor mixed material provided by at least one embodiment of the present disclosure combines the advantage of high stability of the inorganic material with the advantages of being easy to be modified and processed and flexibility of the organic material.

(3) The semiconductor mixed material provided by at least one embodiment of the present disclosure forms one or more functional interfaces between the organic semiconductor material and the inorganic semiconductor material, which not only preserves an intrinsic property of each original component, but also produces a new property by a strong interfacial interaction. That is, a synergism of “1+1>2” is realized.

(4) In the semiconductor mixed material provided by at least one embodiment of the present disclosure, the uniformity of the formed film is improved by adding a coupling agent.

(5) In the semiconductor mixed material provided by at least one embodiment of the present disclosure, the charge mobility at the interface between the inorganic semiconductor material and the organic semiconductor material is improved by adding a room temperature ionic liquid.

(6) In the thin film transistor provided by at least one embodiment of the present disclosure, when the active layer or the organic semiconductor layer is to be formed, the semiconductor mixed material or the organic semiconductor material applied on the base substrate can be solidified directly without using a pattern technology, which reduces the process steps and saves the production cost.

(7) In the thin film transistor provided by at least one embodiment of the present disclosure, the active layer is connected to the organic semiconductor layer made of poly(3-hexylthiophene) through π-π bonds to form stereo channels of the organic semiconductor layer so as to further improve the charge mobility.

Please note that:

(1) the drawings of the embodiments of the present disclosure are only related to the structures mentioned in the embodiments of the present disclosure, and other structures can be further obtained by general designs;

(2) for the sake of clarity, in the drawings for describing the embodiments of the present disclosure, sizes of layers or regions are not drawn according to an actual scale but are exaggerated or diminished; it will be understood that when an element such as a layer, a film, a region or a substrate is referred to as being “on” or “under” another element, the element may be “directly” disposed “on” or “under” another element, or there may be an intermediate element;

(3) the embodiments of the present disclosure and the features therein can be combined with each other to obtain new embodiments in the absence of conflicts.

What are described above is related to only the illustrative embodiments of the present disclosure and not (imitative to the protection scope of the present application. The protection scope of the present application shall be defined by the accompanying claims.

1. A semiconductor mixed material, comprising: an inorganic semiconductor nanoparticle and an organic semiconductor material, wherein the inorganic semiconductor nanoparticle is dispersed in the organic semiconductor material.

2. The semiconductor mixed material according to claim 1, wherein the inorganic semiconductor nanoparticle comprises at least one of an element semiconductor nanoparticle and a compound semiconductor nanoparticle.

3. The semiconductor mixed material according to claim 2, wherein the element semiconductor nanoparticle comprises at least one of silicon nanoparticle and germanium nanoparticle; and
the compound semiconductor nanoparticle comprises at least one of titanium dioxide nanoparticle, zinc sulfide nanoparticle, gallium arsenide nanoparticle, tin oxide nanoparticle, indium oxide nanoparticle, indium antimonide nanoparticle, indium phosphide nanoparticle, cadmium sulfide nanoparticle, bismuth telluride nanoparticle, cuprous oxide nanoparticle, gallium aluminum arsenide nanoparticle, indium gallium arsenide phosphide nanoparticle, gallium arsenide phosphide nanoparticle and copper indium selenide nanoparticle.

4. The semiconductor mixed material according to claim 3, wherein in a case that the inorganic semiconductor nanoparticle is titanium dioxide nanoparticle, at least a portion of a surface of the titanium dioxide nanoparticle is covered with silver.

5. The semiconductor mixed material according to claim 1, wherein the organic semiconductor material comprises at least one of phthalocyanine, triphenyl amine, polyacetylene and polyaromatic ring.

6. The semiconductor mixed material according to claim 5, wherein the polyaromatic ring comprises at least one of polybenzene, polythiophene, polyaniline and polypyrrole.

7. The semiconductor mixed material according to claim 6, wherein the polythiophene comprises poly (3-hexylthiophene).

8. The semiconductor mixed material according to claim 1, further comprising: a coupling agent, wherein the coupling agent comprises at least one of poly (perfluorosulfonic acid), silane coupling agent, ethylene glycol, polyvinyl alcohol and glycerol.

9. The semiconductor mixed material according to claim 1, further comprising: a room temperature ionic liquid, wherein the room temperature ionic liquid comprises at least one of 1,3-dialkyl imidazolium tetrafluoroborate, 1-alkyl-3-methyl imidazolium hexafluorophosphate, 1-butyl-3-methyl imidazolium hexafluorophosphate and 1-allyl-3-methyl imidazolium carboxylate, 1-methyl-3-methyl imidazolium tetrafluoroborate, 1-ethyl-3-methyl imidazolium tetrafluoroborate, N,N-dialkyl imidazolium hexafluorophosphate, N,N-dialkyl imidazolium bromide hexafluorophosphate.

10. A thin film transistor, comprising: an active layer, wherein the active layer comprises the semiconductor mixed material according to claim 1.

11. The thin film transistor according to claim 10, further comprising: a source electrode, a drain electrode and an organic semiconductor layer, wherein the organic semiconductor layer is arranged at a side of the active layer away from the source electrode and the drain electrode.

12. The thin film transistor according to claim 11, wherein a material of the organic semiconductor layer is poly (3-hexylthiophene).

13. An electronic device, comprising the thin film transistor according to claim 10.

14. A manufacturing method of a semiconductor mixed material, comprising: dispersing an inorganic semiconductor nanoparticle in an organic semiconductor material.

15. The manufacturing method according to claim 14, further comprising:
mixing the inorganic semiconductor nanoparticle with a coupling agent and a room temperature ionic liquid, and then being stirred and separated by centrifugation to form a composite structure which has the inorganic semiconductor nanoparticle coated with the coupling agent and the room temperature ionic liquid.

16. The semiconductor mixed material according to claim 2, wherein the organic semiconductor material comprises at least one of phthalocyanine, triphenyl amine, polyacetylene and polyaromatic ring.

17. The semiconductor mixed material according to claim 3, wherein the organic semiconductor material comprises at least one of phthalocyanine, triphenyl amine, polyacetylene and polyaromatic ring.

18. The semiconductor mixed material according to claim 2, further comprising: a coupling agent, wherein the coupling agent comprises at least one of poly (perfluorosulfonic acid), silane coupling agent, ethylene glycol, polyvinyl alcohol and glycerol.

19. The semiconductor mixed material according to claim 2, further comprising: a room temperature ionic liquid, wherein the room temperature ionic liquid comprises at least one of 1,3-dialkyl imidazolium tetrafluoroborate, 1-alkyl-3-methyl imidazolium hexafluorophosphate, 1-butyl-3-methyl imidazolium hexafluorophosphate and 1-allyl-3-methyl imidazolium carboxylate, 1-methyl-3-methyl imidazolium tetrafluoroborate, 1-ethyl-3-methyl imidazolium tetrafluoroborate, N,N-dialkyl imidazolium hexafluorophosphate, N,N-dialkyl imidazolium bromide hexafluorophosphate.

20. The semiconductor mixed material according to claim 3, further comprising: a room temperature ionic liquid, wherein the room temperature ionic liquid comprises at least one of 1,3-dialkyl imidazolium tetrafluoroborate, 1-alkyl-3-methyl imidazolium hexafluorophosphate, 1-butyl-3-methyl imidazolium hexafluorophosphate and 1-allyl-3-methyl imidazolium carboxylate, 1-methyl-3-methyl imidazolium tetrafluoroborate, 1-ethyl-3-methyl imidazolium tetrafluoroborate, N,N-dialkyl imidazolium hexafluorophosphate, N,N-dialkyl imidazolium bromide hexafluorophosphate.
